(19) United States
(12) Patent Application Publication
(10) Pub. No.: US 2008/0061313 A1
(43) Pub. Date: Mar. 13, 2008

(54) PHOTOSENSITIVE CHIP PACKAGE

(76) Inventor: Tzu-Yin YEN, Taichung County (TW)

Correspondence Address: BROWDY AND NEIMARK, P.L.L.C.;624 NINTH STREET, NW, SUITE 300, WASHINGTON, DC, 20001-5303, US

(21) Appl. No.: 11/772,990

(22) Filed: Jul. 3, 2007

(30) Foreign Application Priority Data
Sep. 8, 2006 (TW) 95216097

(51) Int. Cl. H01L 31/0203; H01L 33/00

(52) U.S. Cl. 257/99; 257/434; 257/E33.058; 257/E31.118

(57) ABSTRACT

A photosensitive chip package includes a substrate, a photosensitive chip bonded on the substrate and having a photo-active zone and a photo-inactive zone surrounding the photo-active zone, a plurality of bonding wires electrically connected with the photosensitive chip and the substrate, and an encapsulant covering the photo-inactive zone of the photosensitive chip, the bonding wires and a part of the substrate and having an opening corresponding to the photo-active zone of the photosensitive chip.

### BACKGROUND OF THE INVENTION

1. Field of the Invention

The present invention relates generally to photosensitive chip packages and more particularly, to a photosensitive chip package that can effectively minimize ambient light interference.

2. Description of the Related Art

Photosensitive chips are widely used in various different fields. To enhance the performance and stability of a photosensitive chip, mechanical support strength, environmental factors (such as light sources), electrical connection condition, heat resistivity, and many other factors must be taken into account during packaging.

In a known photosensitive chip package, a transparent encapsulant is used to package a photosensitive chip, forming a shell to enhance the structural strength of the package. The transparent shell allows light to pass to the photosensitive chip. The manufacturing process of this design of photosensitive chip package is much simple. However, ambit light may pass through the transparent shell to interfere with the photosensitive chip, affecting the performance of the photosensitive chip, and lowering the detection reliability.

There is known another design of photosensitive chip package, which uses a transparent cap to cap on the photosensitive chip for guiding incident light to the photosensitive chip. Similar to the aforesaid design, this design cannot eliminate the interference of ambient light. Further, the manufacturing procedure of this design of photosensitive chip package is complicated, resulting in increase of manufacturing cost and time.

Therefore, it is desirable to provide a photosensitive chip package that can eliminate the aforesaid drawbacks.

### SUMMARY OF THE INVENTION

The present invention has been accomplished in view of the above-noted circumstances. It is therefore one objective of the present invention to provide a photosensitive chip package, which can minimize the ambient light interference.

It is another objective of the present invention to provide a photosensitive chip package, which has a simple structure that can save much the manufacturing cost.

To achieve these objectives of the present invention, the photosensitive chip package provided by the present invention comprises a substrate, a photosensitive chip bonded on the substrate and having a photo-active zone and a photo-inactive zone surrounding the photo-active zone, a plurality of bonding wires electrically connected with the photosensitive chip and the substrate, and an encapsulant covering the photo-inactive zone of the photosensitive chip, the bonding wires and a part of the substrate and having an opening corresponding to the photo-active zone of the photosensitive chip.

The photosensitive chip package uses molding technology to substitute for conventional cap package, simplifying the manufacturing process and saving much the manufacturing cost. Further, the invention is practical for use on the condition where the photo-active zone of the photosensitive chip has to be exposed to the outside environment. The encapsulant, which can be made of light-blocking material, effectively limits the detection range of the photosensitive chip, thereby minimizing the ambient light interference and providing high detection reliability.

In a preferred embodiment, the substrate is embodied as a printed circuit board having a plurality of heat dissipative pads and a plurality of heat dissipative passages connected between the photosensitive chip and the heat dissipative pads for heat dissipation.

In another embodiment of the present invention, the substrate is embodied as a lead frame having a plurality of leads electrically connected to the photosensitive chip via the bonding wires.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention, and wherein:

FIG. 1 is a schematic drawing showing a photosensitive chip package in accordance with a first preferred embodiment of the present invention;

FIG. 2 is a schematic drawing showing that the photosensitive chip package according to the first preferred embodiment of the present invention is bonded on a motherboard;

FIG. 3 is a schematic drawing showing a photosensitive chip package in accordance with a second preferred embodiment of the present invention, and

FIG. 4 is a schematic drawing showing a photosensitive chip package in accordance with a third preferred embodiment of the present invention.

### DETAILED DESCRIPTION OF THE INVENTION

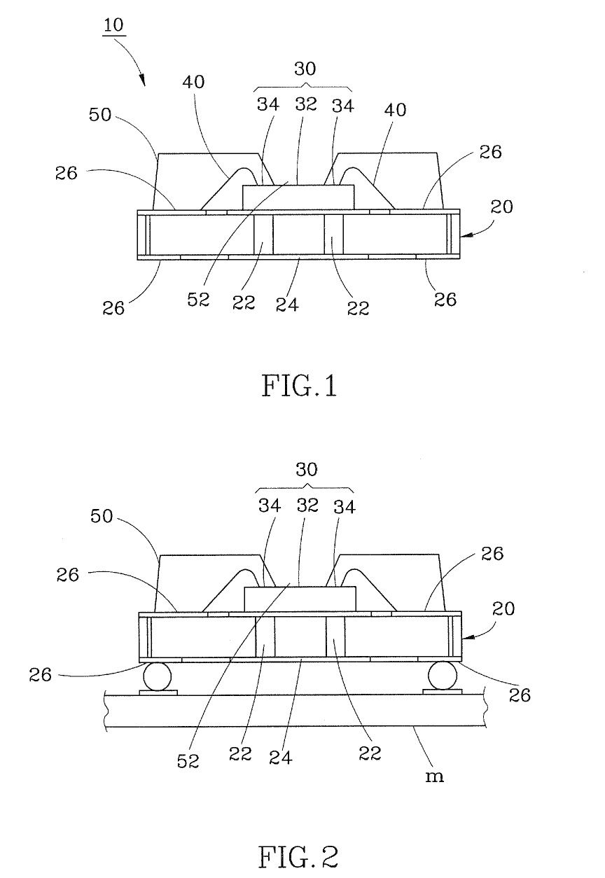

As shown in FIGS. 1 and 2, a photosensitive chip package 10 in accordance with a first preferred embodiment of the present invention comprises a substrate 20, a photosensitive chip 30, a plurality of bonding wires 40, and an encapsulant 50.

The substrate 20 is embodied in this exemplary embodiment as a printed circuit board that can be made of epoxy, organic fiber glass substrates, glass fiber board, polyphenylene either, or ceramics. According to this embodiment, the substrate 20 is preferably made of ceramics. The substrate 20 has a plurality of heat dissipative passages 22, a plurality of heat dissipative pads 24, and a plurality of solder pads 25. The heat dissipative passages 22 each have one end connected to the photosensitive chip 30 and the other end connected to the heat dissipative pads 24 to help dissipation of heat from the photosensitive chip 30. The solder pads 26 are provided at the top and bottom sides of the substrate 20. The solder pads 26 at the top side of the substrate 20 are respectively electrically connected to the solder pads 26 at the bottom side of the substrate 20 for allowing electrical connection of the substrate 2 with other devices.

The photosensitive chip 30 can be a CCD (charge-coupled device) chip, CMOS (Complementary metal oxide semiconductor) chip, or LED (light emitting diode) chip. According to this embodiment, the photosensitive chip 30 is preferably a CMOS chip. The photosensitive chip 30 is installed on the substrate 20, having a photo-active zone 32 and a photo-inactive zone 34. The photo-active zone 32 is at the center of the photosensitive chip 30. The photo-inactive zone 34 surrounds the photo-active zone 32.

The bonding wires 40 are electrically connected to the substrate 20 and the top side of the photo-inactive zone 34 of the photosensitive chip 30.

The encapsulant 50 is made of a light-blocking material molded on the substrate 20 and the photo-inactive zone 34 of the photosensitive chip 30, covering a part of the substrate 20, the photo-inactive zone 34 and the bonding wires 40. The encapsulant 50 has an opening 52 at a top side thereof corresponding to the photo-active zone 32 so that light can pass through the opening 52 and fall upon the photo-active zone 32.

Subject to the aforesaid arrangement, the invention uses molding technology to seal the photo-inactive zone 34 of the photosensitive chip package 10. The opening 52 of the encapsulant 50 limits the detection range of the photosensitive chip 30, lowering the interference of ambient noises, i.e., the photosensitive chip package 10 has better stability. Further, the invention simplifies the manufacturing process, saving much time and labor.

FIG. 2 is a schematic drawing illustrating that the photosensitive chip package 10 of the present invention is installed on a motherboard M. As illustrated, the solder pads 26 at the bottom side of the substrate 20 are bonded to the motherboard M by means of BGA (ball grid array). This application example is to show the connection status between the photosensitive chip package 10 and the motherboard M. and the relative bonding structure.

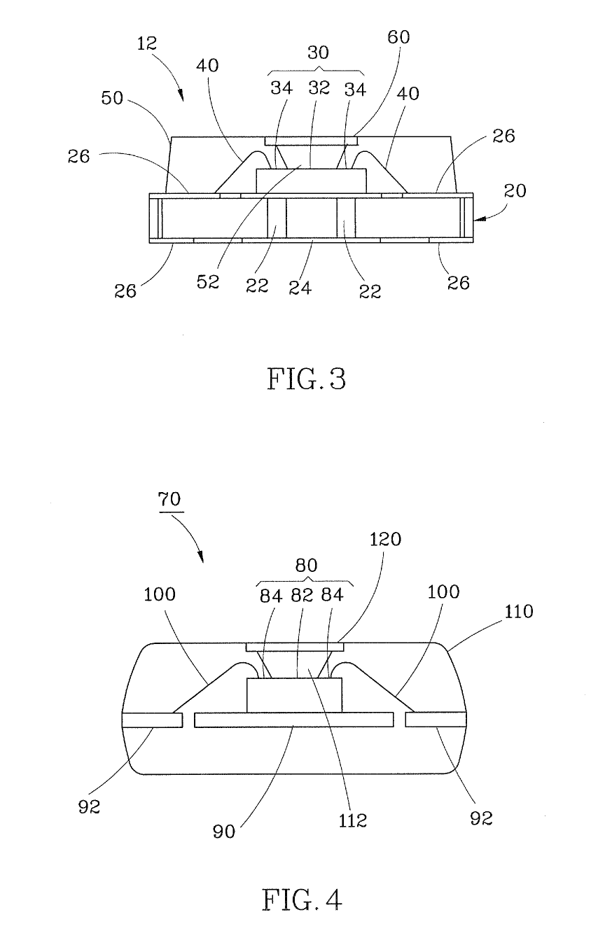

FIG. 3 illustrates a photosensitive chip package 12 in accordance with a second preferred embodiment of the present invention. Similar to the aforesaid first embodiment, the photosensitive chip package 12 comprises a substrate 20, a photosensitive chip 30, a plurality of bonding wires 40, and an encapsulant 50. This second embodiment further comprises a light transmissive glass 60 provided at the top side of the encapsulant 50 to shield the photo-active zone 32, providing a protection to the photo-active zone 32.

FIG. 4 illustrates a photosensitive chip package 70 in accordance with a third embodiment of the present invention. According to this third embodiment, the photosensitive chip package 70 comprises a photosensitive chip 80, a lead frame 90, a plurality of bonding wires 100, an encapsulant 110, and a light transmissive glass 120.

The photosensitive chip 80 can be a CCD (charge-coupled device) chip, CMOS (Complementary metal oxide semiconductor) chip, or LED (light emitting diode) chip. According to this embodiment, the photosensitive chip 80 is a CCD chip. The photosensitive chip 80 has a photo-active zone 82 and a photo-inactive zone 84. The photo-active zone 82 is at the center of the photosensitive chip 80. The photo-inactive zone 84 surrounds the photo-active zone 82.

The lead frame 90 is arranged at the bottom side of the photosensitive chip 80 for supporting the photosensitive chip 10.

The bonding wires 100 are electrically connected between the top side of the photo-inactive zone 84 of the photosensitive chip 80 and the corresponding leads 92 of the frame 90.

The encapsulant 110 is molded on the photosensitive chip 80 and the lead frame 90, covering the photo-inactive zone 84 of the photosensitive chip 80, a part of the lead frame 90, and all of the bonding wires 100. The encapsulant 110 has an opening 112 corresponding to the photo-active zone 82 so that light can pass through the opening 112 and fall upon the photo-active zone 82.

The light transmissive glass 120 is provided at the top side of the encapsulant 110 to shield the photo-active zone 82, providing a protection to the photo-active zone 82.

Unlike the use of the substrate 20 with solder pads 26 in the aforesaid first embodiment of the present invention, the photosensitive chip package 70 of the third embodiment of the present invention uses the lead frame 90 as an electrical connection means for the connection of the photosensitive chip 80 to external devices. This third embodiment achieves the same effects as the aforesaid first embodiment of the present invention.

As stated above, the invention uses molding technology to substitute for conventional cap package, simplifying the manufacturing process and saving much the manufacturing cost. Further, the invention is practical for use on the condition where the photo-active zone of the photosensitive chip has to be exposed to the outside environment for action. The encapsulant of the invention limits the detection range of the photosensitive chip, minimizing the ambient light interference and providing a high reliability.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A photosensitive chip package comprising:
a substrate;
a photosensitive chip bonded on the substrate, the photosensitive chip having a photo-active zone and a photo-inactive zone surrounding the photo-active zone;
a plurality of bonding wires electrically connected with the photosensitive chip and the substrate; and
an encapsulant covering the photo-inactive zone of the photosensitive chip, the bonding wires and a part of the substrate and having an opening corresponding to the photo-active zone of the photosensitive chip.

2. The photosensitive chip package as claimed in claim 1, wherein the substrate comprises a plurality of solder pads disposed at one side thereof for electrical connection of external devices.

3. The photosensitive chip package as claimed in claim 1, wherein the substrate has a plurality of heat dissipative passages each having an end connected to the photosensitive chip.

4. The photosensitive chip package as claimed in claim 3, wherein the substrate comprises a plurality of heat dissipative pads; the heat dissipative passages each have the other end respectively connected to the heat dissipative pads.

5. The photosensitive chip package as claimed in claim 1, further comprising a light transmissive glass disposed at the encapsulant to shield the photo-active zone of the photosensitive chip.

6. The photosensitive chip package as claimed in claim 1, wherein the photosensitive chip is one of charge-coupled device chip, complementary metal oxide semiconductor chip and light emitting diode chip.

7. A photosensitive chip package comprising:
a lead frame;
a photosensitive chip bonded on the lead frame, the photosensitive chip having a photo-active zone and a photo-inactive zone surrounding the photo-active zone;
a plurality of bonding wires electrically connected with the photosensitive chip and the lead frame; and
an encapsulant covering the photo-inactive zone of the photosensitive chip, the bonding wires and a part of the lead frame and having an opening corresponding to the photo-active zone of the photosensitive chip.

8. The photosensitive chip package as claimed in claim 7, further comprising a light transmissive glass disposed at the encapsulant to shield the photo-active zone of the photosensitive chip.

9. The photosensitive chip package as claimed in claim 7, wherein the photosensitive chip is one of charge-coupled device chip, complementary metal oxide semiconductor chip and light emitting diode chip.
